(19) United States
(12) Patent Application Publication
(10) Pub. No.: US 2020/0274056 A1
(43) Pub. Date: Aug. 27, 2020

(54) MAGNETOSTRICTIVE ELEMENT AND METHOD FOR MANUFACTURING SAME

(71) Applicant: Panasonic Intellectual Property Management Co., Ltd., Osaka (JP)

(72) Inventors: MASAYA SHIROTANI, Osaka (JP); TAICHI NAKAMURA, Osaka (JP); KAZUKI SAKAI, Osaka (JP)

(21) Appl. No.: 16/775,239

(22) Filed: Jan. 28, 2020

(30) Foreign Application Priority Data
Feb. 25, 2019 (JP) 2019-031404

(51) Int. Cl. H01L 41/20; H01L 41/12; H01L 41/47; H02N 2/18

(52) U.S. Cl. CPC H01L 41/20; H02N 2/186; H01L 41/47; H01L 41/125

(57) ABSTRACT

A magnetostrictive element that can exhibit a sufficiently large magnetostriction amount in a longitudinal direction is formed of a single crystal alloy magnetostrictive material. The magnetostrictive element has a shape of a plate-shaped rectangular parallelepiped, a main plane of the plate-shaped rectangular parallelepiped includes a plurality of magnetic domains that are regions where atomic magnetic moments are arranged in the same direction and whose width is 10 μm to 200 μm, and a total area rate of a magnetic domain where an angle difference between a lateral direction of the main plane and a direction of the magnetic moments of the magnetic domain is 10° or less to the main plane is 60% to 100%.

### TECHNICAL FIELD

The technical field relates to a magnetostrictive element formed of a single crystal alloy magnetostrictive material and to a method for manufacturing the same.

### BACKGROUND

In recent years, it is expected that a world where things, which have a function of autonomously performing communication, exchange information with each other and automatically control each other, that is, a world of the Internet of Things (IoT) will arrive. When the IoT permeates the society, a large number of IoT devices having a communication function are available. An electric power source is required to operate the IoT devices, such as a sensor. However, when the number of devices becomes enormous, it is difficult to secure the electric power source in terms of wiring and maintenance time and cost. Therefore, in order to implement the IoT, an electric power supply technology suitable for the IoT devices is required. Based on such a background, “energy harvesting” is considered important, which is a technology for converting minute energy anywhere in our lives into electric power for use. Vibration, which is one of energy sources, is generated every time an automobile, a railroad, a machine, a person, or the like moves. Therefore, there are many generation places, and the vibration is an energy source not influenced by weather and climate. Therefore, it is considered that construction of a system that supplies electric power, by vibration electric power generation, for an application linked with the movement of these mobile objects can be a clue to the implementation of the IoT.

Vibration electric power generation methods are classified into four methods: a magnetostrictive method, a piezoelectric method, an electrostatic induction method, and an electromagnetic induction method. The magnetostrictive method is a method in which a magnetic flux leaked to outside is converted into electricity through a wound coil along with a change in a magnetic field inside a magnetostrictive material by applying a stress. Since an internal resistance is smaller than those of other methods, an electric power generation amount is large. Further, since a metal alloy is used as the magnetostrictive material, a feature of excellent durability is obtained. Therefore, the magnetostrictive method can be expected as a method in which the durability can be improved, which is one of problems of a magnetostrictive vibration electric power generation device or a magnetostrictive element.

Examples of a magnetostrictive element in the related art include a magnetostrictive element formed by cutting a FeGa single crystal alloy by electric discharge machining and by performing alignment with a <100> orientation of a single crystal. In order to manufacture such a magnetostrictive element, a FeGa alloy in a molten state is pulled out from the inside of a tubular furnace to the outside of the tubular furnace by a lifting device at a constant speed, and the molten alloy is solidified in one direction from a lower portion to an upper portion. Crystal growth can be performed in a direction of the <100> orientation by performing the solidification in this manner. Thereafter, the solidified steel ingot is separated into a single crystal, and cutting out is performed by the electric discharge machining while performing alignment with the <100> orientation of the single crystal, so that individual magnetostrictive elements are acquired (see WO 2016/121132).

### SUMMARY

When the magnetostrictive element is actually applied to a magnetostrictive vibration electric power generation device or the like, from viewpoints of improving an electric power generation amount and a device quality, an important issue is how to sufficiently increase a magnetostriction amount in a longitudinal direction of the plate-shaped magnetostrictive element and how to reduce a variation in magnetostriction characteristics for respective applied magnetostrictive elements. However, in the magnetostrictive element manufactured by the method of the related art as described above, the variation is present in the magnetostrictive characteristics. Therefore, when the magnetostrictive element is cut out from the single crystal alloy, in a case where a cutting out direction thereof is a direction of an easy-magnetization axis and is a direction normal to a crystal orientation <100> plane where a magnetic domain is present only in a plane of the magnetostrictive element, a variation is also generated in the electric power generation amount due to the variation in the magnetostrictive characteristics, and a usable magnetostrictive element is limited, thus decreasing a yield. Here, the magnetic domain is a region where atomic magnetic moments are arranged in the same direction, and a width of the region is 10 μm to 200 μm. Further, the single crystal alloy has a structure in which a plurality of magnetic domains occupy an entire main plane of the magnetostrictive element.

When the magnetostrictive elements are cut out from the single crystal alloy, in the method of the related art, since the magnetostrictive elements are cut out in the same direction, a magnetic domain structure varies from element to element, thus also generating a variation in the magnetostriction amount. In some cases, a magnetostrictive element can be generated which does not exhibit a sufficiently large magnetostriction amount in the longitudinal direction. Therefore, an object of the disclosure is to provide a magnetostrictive element that can exhibit a sufficiently large magnetostriction amount in a longitudinal direction. Further, an object of the disclosure is to provide a magnetostrictive element that can reduce a variation in magnetostrictive characteristics of the magnetostrictive element and accordingly improve a yield, and to provide a method for manufacturing the magnetostrictive element.

According to an aspect of the disclosure, there is provided a magnetostrictive element formed of a single crystal alloy magnetostrictive material, in which the magnetostrictive element has a shape of a plate-shaped rectangular parallelepiped,

a main plane of the plate-shaped rectangular parallelepiped includes a plurality of magnetic domains that are regions where atomic magnetic moments are arranged in the same direction and whose width is 10 μm to 200 μm, and a total area rate of a magnetic domain where an angle difference between a lateral direction of the main plane and a direction of the magnetic moments of the magnetic domain is 10° or less to the main plane is 60% to 100%.

According to an aspect of the disclosure, there is provided a method for manufacturing a magnetostrictive element. The method includes:

preparing a magnetostrictive material of single crystal alloy subjected to a heat treatment and produced into a columnar shape;

cutting out, from the single crystal alloy magnetostrictive material, a first test element having a first dimension and a second dimension smaller than the first dimension respectively in a first direction parallel to a <100> crystal orientation of a single crystal alloy and in a second direction orthogonal to the first direction;

dividing the first test element into a plurality of sections along the first direction, and cutting out at least one second test element from each of the plurality of sections;

observing a magnetic domain that is an area where atomic magnetic moments are arranged in the same direction and whose width is 10 μm to 200 μm for each of the second test elements; and cutting out a magnetostrictive element, by using an observation result of the magnetic domains of the second test elements corresponding to the plurality of sections, from a remaining portion where the first test element of the single crystal alloy magnetostrictive material is cut out, in which

the magnetostrictive element has a shape of a plate-shaped rectangular parallelepiped, a main plane of the plate-shaped rectangular parallelepiped includes a plurality of magnetic domains that are regions where the atomic magnetic moments are arranged in the same direction and whose width is 10 μm to 200 μm, and a total area rate of a magnetic domain where an angle difference between a lateral direction of the main plane and a direction of the magnetic moments of the magnetic domain is 10° or less to the main plane is 60% to 100%.

According to the magnetostrictive element of the disclosure, the total area rate of (i) the magnetic domain where the angle difference between the lateral direction of the main plane and the orientation of the magnetic domains is 10⁰ or less among a plurality of magnetic domains provided on the main plane to (ii) the main plane of the plate-shaped rectangular parallelepiped is set to 60% to 100%, so that a magnetostrictive element can be provided which exhibits a sufficiently large magnetostriction amount in the longitudinal direction of the main plane.

Further, according to the method for manufacturing a magnetostrictive element of the disclosure, the first test element and the second test element are sequentially cut out from the single crystal alloy magnetostrictive material, and the magnetostrictive element of the disclosure can be cut out from the remaining portion of the single crystal alloy magnetostrictive material by using the observation result of the magnetic domains of the second test elements. Therefore, a variation in magnetostrictive characteristics of the magnetostrictive element can be reduced, a portion that has not been used until now due to the large variation can be used, and a yield can be improved.

### BRIEF DESCRIPTION OF THE DRAWINGS

FIG. 1A is a schematic perspective view of a magnetostrictive element according to one embodiment of the disclosure, and FIG. 1B is an enlarged schematic view of a region P on a main plane of the magnetostrictive element of FIG. 1A.

FIG. 2 is a view combining coordinates and the schematic perspective view of the magnetostrictive element according to the embodiment of the disclosure.

FIG. 3 is a flowchart showing a method for manufacturing a magnetostrictive element according to the embodiment of the disclosure.

FIG. 4 is a schematic view illustrating characteristics of the magnetostrictive element according to the embodiment of the disclosure.

### DESCRIPTION OF EMBODIMENTS

Hereinafter, an embodiment of the disclosure will be described with reference to the accompanying drawings.

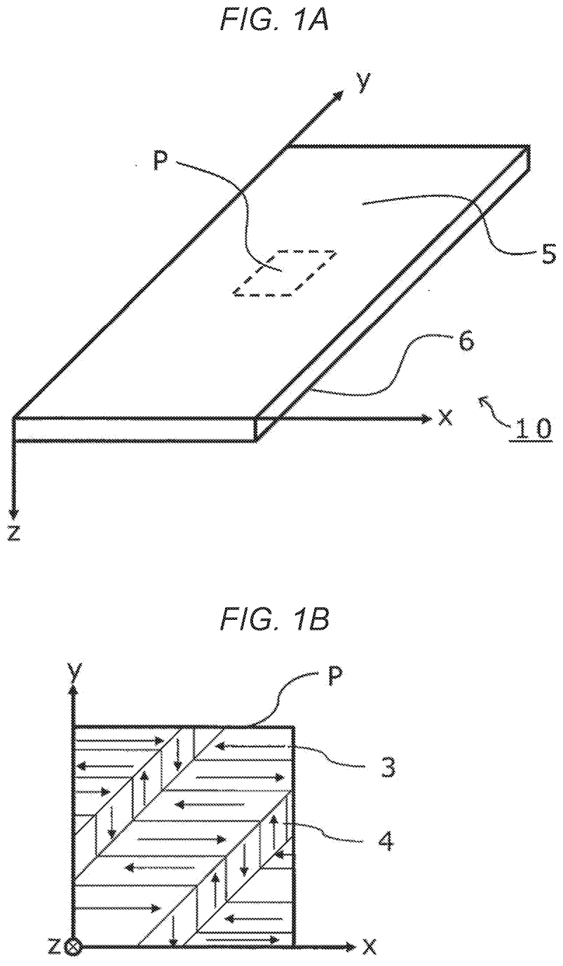

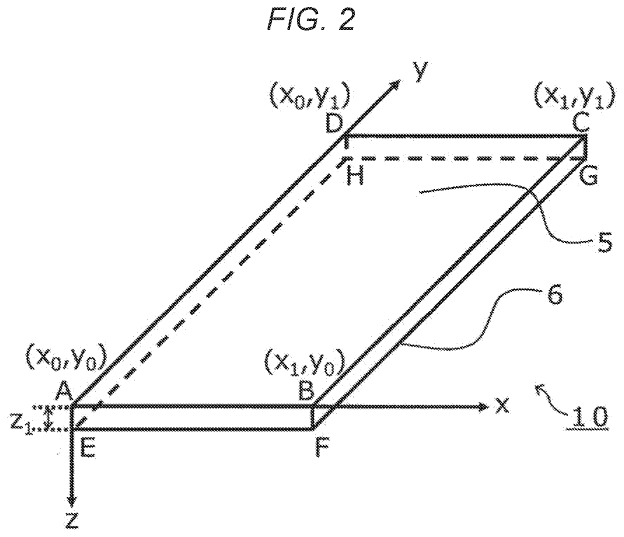

FIG. 1A is a schematic perspective view of a magnetostrictive element 10 according to the present embodiment, and FIG. 1B is an enlarged schematic view of a region P on a main plane of the magnetostrictive element 10. FIG. 2 is a view combining coordinates and the schematic perspective view of the magnetostrictive element 10 according to the present embodiment.

The magnetostrictive element 10 of the present embodiment is formed of a single crystal alloy magnetostrictive material, and has a shape of a plate-shaped rectangular parallelepiped as shown in FIG. 1A. The term “plate-shaped rectangular parallelepiped” in the disclosure means a shape including three pairs of planes that constitute a rectangular parallelepiped, each pair of planes facing each other and having equal area, in which one pair of planes occupying a largest area are set as the “main planes” (corresponding to surfaces of a plate), a direction along a largest dimension among dimensions of each of the main planes is set as a “longitudinal direction”, a direction along a relatively small dimension and orthogonal to the longitudinal direction is set as a “lateral direction”, and a distance between these main planes (corresponding to a thickness of the plate) is smaller (thinner) than the dimension of the main plane in the longitudinal direction and the dimension of the main plane in the lateral direction.

The term “main plane” means the above-described “main planes” 5 and 6 (one pair of planes occupying the largest area among the three pairs of planes that constitute the rectangular parallelepiped, each pair of planes facing each other and having equal area) in a narrow sense, but can mean any plane parallel to these main planes 5 and 6 (or an x-y plane to be described below) in a broad sense.

More specifically, as shown in FIG. 1A, the magnetostrictive element 10 in the present embodiment has the one pair of main planes 5 and 6 occupying the largest area among the three pairs of planes that constitute the rectangular parallelepiped, each pair of plane facing each other and having equal area (in the perspective views of FIG. 1A and FIG. 2, the main plane 6 is a plane positioned on a back side of the magnetostrictive element 10 and facing the main plane 5). Thereafter, when vertices of the rectangular parallelepiped are vertices A to H as shown in FIG. 2, the vertex A is set as an origin (x₀=y₀=z₀=0), a y-axis is set in the longitudinal direction (direction along a relatively long edge AD) of the main plane 5 including the vertex A, an x-axis is set in the lateral direction (direction along a relatively short edge AB) of the main plane 5 including the vertex A, and a z-axis is set in a thickness direction (direction along an edge AE) between the main planes 5 and 6 from the vertex A (the x-, y- and z-axes form a coordinate system where the x, y and z axes are orthogonal to one another). When a dimension of the main planes 5 and 6 in the longitudinal direction is set as y₁, a dimension of the main planes 5 and 6 in the lateral direction is set as x₁, and a distance (length of the shortest edge AE) between the main planes 5 and 6 is set as z₁, coordinates (x, y, z) of the vertices are shown as follows: A (x₀, y₀, z₀), B (x₁, y₀, z₀), C (x₁, y₁, z₀), D (x₀, y₁, z₀) , E (x₀, y₀, z₁) , F (x₁, y₀, z₁) , G (x₁, y₁, z₁), and H (x₀, y₁, z₁). Here, x₀=y₀=z₀=0, and y₁>x₁>z₁>0 are satisfied.

In other words, as clearly shown in FIG. 2, the magnetostrictive element 10 has a plane formed by the x-axis and the y-axis, that is a plane (the main planes 5 and 6 and a cross section parallel thereto) surrounded by points (x₀, y₀), (x₁, y₀), (x₁, y₁), (x₀, y₁) as coordinates (x, y) in the x-y plane, and has the dimension z₁ in the thickness direction along the z-axis. Here, x₀=y₀=0, and y₁>x>z₁>0 are satisfied.

The main plane (more specifically, the main planes 5 and 6) of the magnetostrictive element 10 includes a plurality of magnetic domains. The term “magnetic domain” means a region where atomic magnetic moments are arranged in the same direction and whose width is 10 μm to 200 μm. The “width” of the magnetic domain means a minimum distance between magnetic domain walls that partition a certain magnetic domain and face each other. Usually, the entire main plane can be occupied by a plurality of magnetic domains.

How the plurality of magnetic domains exist on the main plane and in which direction the magnetic moments are oriented in each magnetic domain (hereinafter, also referred to as a “magnetic domain structure” in this specification) can be examined by observing the main plane by, for example, a method using a Kerr effect microscope. The Kerr effect microscope is a microscope that uses a Kerr effect in which elliptically polarized light is formed when linearly polarized light is incident on a specific material, an observation range thereof is smaller than that of an optical microscope, and only an in-plane magnetic domain structure can be extracted and observed.

In the magnetostrictive element 10 of the present embodiment, a total area rate of the magnetic domain where an angle difference between the lateral direction of the main plane and the direction of the magnetic moments of the magnetic domain is 10° or less to the main plane is 60% to 100%. Such a rate maybe calculated for at least one of the two facing main planes 5 and 6 (since the thickness z₁ is small, it maybe considered that there is substantially no difference between the main planes 5 and 6 and a parallel plane therebetween), further may be calculated by observing the entire main planes 5 and 6, and typically may be calculated by observing a partial region of either one of the main planes. For example, a certain region of the main plane is set as an observation target. For each magnetic domain in the region of the observation target, the angle difference between the lateral direction of the main plane (x-axis direction in the present embodiment) and the direction of the magnetic moments of the magnetic domain may be examined, a total area of the magnetic domains whose angle difference is 10° or less may be calculated, and a rate of the total area of the magnetic domains whose angle difference is 10° or less to an area of the region of the observation target may be calculated. Further, in the disclosure, the “angle difference between the lateral direction of the main plane and the direction of the magnetic moments of the magnetic domain” or simply the “angle difference” means an angle formed by two directions (therefore, a minimum value of the angle difference is 0°). The “angle difference is 10° or less” means that when one direction (for example, the lateral direction of the main plane) is set as a reference (0°) and the angle formed by turning counterclockwise from the reference to the other direction (for example, the direction of the magnetic moments of the magnetic domain) is measured, the measured angle is within ±10°.

Typically, FIG. 1B schematically shows the region P of the main plane 5 in an enlarged manner, the directions of the atomic magnetic moments in the magnetic domain are indicated by arrows, and the magnetic domain walls, which are boundaries of the magnetic domains, are indicated by thin solid lines. In the schematic example of FIG. 1B, the region P of the main plane 5 is occupied by the plurality of magnetic domains. When the angle of the direction of the magnetic moments of each magnetic domain measured counterclockwise from the x-axis direction that is the lateral direction of the main plane is examined, and the angle difference between the lateral direction of the main plane and the direction of the magnetic moments of the magnetic domain is examined, the angle of a magnetic domain 3 is 0° or 180°, and thus the angle difference is 0°; the angle of a magnetic domain 4 is 90°or 270°, and thus the angle difference is 90°. Thus, in the example shown in the figure, an area rate of the magnetic domain 3, corresponding to an angle difference of 10° or less, to the observation region P of the main plane is calculated, and the area rate is 70%.

In the present embodiment, the magnetostrictive material may be represented by the following formula (1)

Fe_{(100-α)}Ga_{α} (1)

(wherein α is a content (at %) of Ga and satisfies 14≤α≤19), or may be represented by the following formula (2)

Fe_{(100-α-β)}Ga_{α}X_{β} (2)

(wherein α is a content (at %) of Ga and β is a content (at %) of X; X is one or more elements selected from the group consisting of Ce, Sm, Eu, Gd, Tb, Dy, Cu, and C; and α and β satisfy 14≤α≤19 and 0.05≤β≤1.)

The magnetostrictive material (single crystal alloy) represented by the formula (1) exhibits excellent magnetostrictive characteristics when Ga is dissolved in Fe.

The magnetostrictive material (single crystal alloy) represented by the formula (2) exhibits further excellent magnetostrictive characteristics by replacing part of Ga with a third element (one or more elements selected from the group consisting of Ce, Sm, Eu, Gd, Tb, Dy, Cu and C, and particularly one element selected from the above group) . However, a solid solution amount of an element other than Fe with respect to Fe is contained in an amount that does not change a structure of the crystal. Specifically, the content is 20 at % or less, which is a sufficiently small amount with respect to 30 at % considered to be a solid solution limit for Fe. Further preferably, in the above formula (2), X, as the third element, may be one or more elements selected from the group consisting of Ce, Sm, Cu and C. Among them, Ce and Sm are particularly preferable because the magnetostrictive characteristics are considered to be improved by a quadrupole moment.

In the present disclosure, a content (also referred to as a concentration) of each element in the magnetostrictive material (single crystal alloy) represented by the formula (1) or (2) is a rate of the number of atoms of each element to the number of atoms of the entire magnetostrictive material (single crystal alloy), and refers to a value expressed using a unit of at % (atomic percent). Specifically, the content refers to a value obtained by measuring the content of the element by analyzing the magnetostrictive material (single crystal alloy) using fluorescent X-ray analysis (XRF). Specifically, the content refers to a value obtained by performing spot analysis using the XRF of the magnetostrictive element 10. More specifically, the content refers to a content (at %) obtained by analyzing an optional point on the x-y plane of the magnetostrictive element 10 using the XRF. Further, the magnetostrictive material (single crystal alloy) constituting the magnetostrictive element 10 in the present embodiment may contain an inevitably mixed trace element (for example, oxygen less than 0.005 at %) as long as the magnetostrictive material is substantially formed of the elements described above.

The magnetostrictive element 10 shown in FIGS. 1A-1B is formed of the single crystal alloy magnetostrictive material. For convenience of explanation, the vertex A of the main plane 5 of the magnetostrictive element 10 is set as the origin, and the x-axis in the lateral direction, the y-axis in the longitudinal direction, and the z-axis in the thickness direction are set, which are orthogonal to one another. The magnetostrictive element 10 has the shape of the plate-shaped rectangular parallelepiped including the two main planes 5 and 6 that are parallel to the x-y plane and face each other, but the shape is not limited thereto. Specifically, as long as the total area rate of (i) the magnetic domain where the angle difference between the lateral direction and the direction of the magnetic moments of the magnetic domain is within 10° to (ii) the plane having the dimension (y₁) of the longitudinal direction and the dimension (x₁) of the lateral direction orthogonal to the longitudinal direction and including the longitudinal direction and the lateral direction of the magnetostrictive element is 60% to 100% (preferably, the magnetostrictive element 10 is formed of the magnetostrictive materials represented by the above formula (1) or (2)), the magnetostrictive element 10 may have an optional shape in accordance with a magnetostrictive device or the like to which the magnetostrictive element is applied. Examples of such a shape can include a rectangular parallelepiped shape, a polygonal column shape, and a pillar shape or another three-dimensional shape having a semicircular cross section.

New characteristics of the magnetostrictive element 10 will be described in detail below, together with a method for manufacturing the magnetostrictive element 10 in the embodiment of the disclosure.

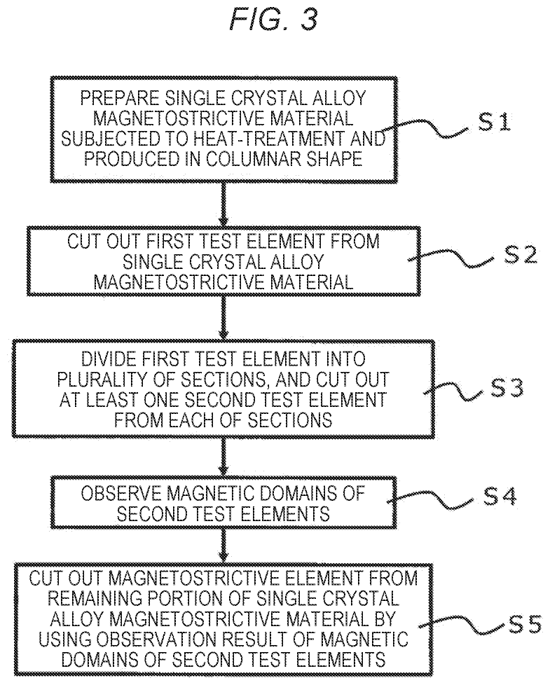

FIG. 3 is a flowchart showing the method for manufacturing the magnetostrictive element 10 in the present embodiment. The method for manufacturing the magnetostrictive element 10 in the present embodiment includes the following steps S1 to S5.

S1: A single crystal alloy magnetic material subjected to a heat treatment and produced in a columnar shape is prepared.

S2: A first test element is cut out from the single crystal alloy magnetic material.

S3: The first test element is divided into a plurality of sections, and at least one second test element is cut out from each of the plurality of sections.

S4: Magnetic domains of the second test elements are observed.

S5: A magnetostrictive element is cut out from the remaining portion of the single crystal alloy magnetostrictive material by using an observation result of the magnetic domains of the second test elements.

First, in S1, the single crystal alloy magnetostrictive material represented by the above formula (1) or (2), subjected to a heat treatment, and produced in the columnar shape is prepared. The method for producing such a magnetostrictive material is not particularly limited, and a suitable method according to a desired composition, size, and shape of the single crystal alloy is used. Examples of the method include a Czochralski method (CZ method), a Bridgman method, or a rapid solidification method. When performing manufacturing by the CZ method, a chemical composition and a crystal orientation can be accurately manufactured in a large crystal. More specifically, for example, a columnar-shaped single crystal alloy is produced by the CZ method.

For example, when the columnar-shaped single crystal alloy represented by the above formula (1) or (2) is produced by the CZ method, a concentration (at %) of an element other than Fe, for example, Ga may be increased (for example, monotonically increased) in a direction from an early growth stage portion (portion pulled out from a crucible first) corresponding to an upper portion of the columnar-shaped single crystal alloy toward a late growth stage portion (portion pulled out from the crucible later) corresponding to a lower portion of the columnar-shaped single crystal alloy. This is because a liquidus line and a solidus line have widths in a composition of an FeGa-based alloy. Accordingly, when producing the single crystal alloy by the CZ method, the single crystal alloy satisfying the content of each element of the single crystal alloy represented by the above formula (1) or (2) can be obtained by performing the analysis using the XRF as described above and making appropriate adjustment, even when the concentration of Ga is monotonically increased, for example.

Thereafter, in S2, the first test element, which has a first dimension and a second dimension smaller than the first dimension respectively in a first direction parallel to a <100> crystal orientation of the single crystal alloy and a second direction orthogonal to the first direction, is cut out from the single crystal alloy magnetostrictive material prepared in S1.

When the columnar-shaped single crystal alloy magnetostrictive material prepared in S1 has the <100> crystal orientation in a column height direction, the first test element, which has the first dimension in the first direction parallel to the column height direction (<100> crystal orientation) and the second dimension (smaller than the first dimension) in the direction orthogonal to the first direction, is cut out from a straight body portion of the magnetostrictive material. Here, the straight body portion is a portion of the columnar-shaped single crystal alloy magnetostrictive material prepared in S1 having a maximum diameter of a column from a bottom surface to a top surface of the column. The first test element is cut out such that a central axis of the straight body portion along the column height direction coincides with a central axis of the first test element parallel to the first direction, and the pair of main planes of the first inspection element facing each other is disposed in parallel to the column height direction. The first dimension of the first test element may be a dimension that extends from the bottom surface to the top surface of the straight body portion, but is not limited thereto. The second dimension is not particularly limited as long as the second dimension is smaller than the first dimension, and can be appropriately set in consideration of ease of handling and the like.

In the present disclosure, the <100> crystal orientation of the single crystal alloy can be determined by a known method, and in particular, can be determined by an electron backscatter diffraction (EBSD) method.

Any known method can be used as the method for cutting out the first test element. For example, the first test element can be cut out by wire electric discharge machining or the like. Any known method can also be used as a method for cutting out the second test elements and the magnetostrictive element, which will be described below.

Thereafter, in S3, the first test element cut out in S2 is divided into a plurality of sections along the first direction, and at least one second test element is cut out from each of the plurality of sections. At least one second test element may be cut out from each section after the first test element is actually divided into the plurality of sections, or at least one second test element may be directly cut out from each section of the first test element assumed to be divided without actually dividing the first test element. The second test element has a shape of a plate-shaped rectangular parallelepiped. Two main planes of the second test element are preferably parallel to a plane of the first test element having the first direction and the second direction. When a dimension along the first direction of the second test element is set as a length, a dimension along the second direction of the second test element is set as a width, and a distance between the two main planes of the second test element is set as a thickness, the length and the width may be the same or may be different, but the thickness is smaller than the length and the width.

Although the present embodiment is not limited thereto, the plurality of sections can be, for example, portions obtained by dividing the first test element into three sections along the first direction. More specifically, the first dimension of the first test element may be divided into three sections, and the second test elements may be cut out one by one from the three sections of the first test element. Ina more detailed example, the first test element is divided into three sections along the first direction (a length of each section is ⅓ of the first dimension). The second test element having a length of 5 mm, a width of 5 mm, and a thickness of 1 mm may be cut out from a central portion of an upper edge of the section corresponding to a ⅓ length on an upper side of the first test element in the first direction, the second test element having a length of 5 mm, a width of 5 mm, and a thickness of 1 mm may be cut out from a central portion of the section corresponding to a ⅓ length on a middle side of the first test element in the first direction, and the second test element having a length of 5 mm, a width of 5 mm, and a thickness of 1 mm may be cut out from a central portion of a lower edge of the section corresponding to a ⅓ length on a lower side of the first test element in the first direction.

Thereafter, in S4, for each of the second test elements cut out in S3, the magnetic domain that is a region where the atomic magnetic moments are arranged in the same direction and whose width is 10 μm to 200 μm is observed. Although the present embodiment is not limited thereto, for example, when the second test element is viewed from one main plane, the length and the width are each divided into a plurality of sections (both the length and the width are divided into, for example, 3 or 5 equal portions). Among these sections, the magnetic domain is observed in a section S (an area of 100 μm² or more and 1 mm² or less) including a center of gravity of the second test element. The magnetic domain of the second test element can be observed in a similar manner by applying the method described above when examining the magnetic domain structure of the magnetostrictive element. For example, a method using the Kerr effect microscope can be used.

For each of the second test elements, the magnetic domain is observed to determine a cutting out direction of the magnetostrictive element such that the total area rate of (i) the magnetic domain where the angle difference between the lateral direction of the main plane of the magnetostrictive element and the direction of the magnetic moments of the magnetic domain when producing the magnetostrictive element is 10° or less to (ii) the area of the observation region is 60% to 100%. The cutting out direction of the magnetostrictive element can be selected in consideration of a size and a yield of the magnetostrictive element to be finally cut out.

Thereafter, in S5, the magnetostrictive element is cut out from the remaining portion of the single crystal alloy magnetostrictive material by using the observation result of the magnetic domains of the second test elements acquired in S4. At this time, from the remaining portion, the magnetostrictive element is cut out from a portion corresponding to the section of the first test element where the second test element is cut out such that the cutting out direction determined based on the observation result of the magnetic domains of the second test elements coincides with the longitudinal direction of the magnetostrictive element. For example, from the remaining portion of the straight body portion where the first test element is cut out, a plate-shaped body is cut out to be parallel to the plane having the first direction and the second direction of the first test element. From the plate-shaped body, the magnetostrictive element 10 is cut out such that the cutting out direction determined in S4 is the longitudinal direction for the sections corresponding to the ⅓ lengths, on the upper side, the middle side, and the lower side, of the straight body portion in the first direction.

Accordingly, the magnetostrictive element 10 of the present embodiment is acquired. With reference to FIGS. 1A and 2, the magnetostrictive element 10 can have characteristics exhibiting a sufficiently large magnetostriction amount in the longitudinal direction (y-axis direction) when a magnetic field parallel to the x-y plane is applied.

The shape to be cut out is not limited to, as described above in the shape of the magnetostrictive element 10, the shape of the plate-shaped rectangular parallelepiped including the two main planes 5 and 6 that are parallel to the x-y plane and face each other. Specifically, the magnetostrictive element 10 may be cut into a shape where the dimension (y₁) in the longitudinal direction and the dimension (x₁) in the lateral direction orthogonal to the longitudinal direction are provided, and the total area rate of (i) the magnetic domain where the angle difference between the lateral direction and the direction of the magnetic moments of the magnetic domain is within 10° to (ii) the plane having the longitudinal direction and the lateral direction of the magnetostrictive element is 60% to 100%.

The plate-shaped body before the magnetostrictive element is cut out may have a magnetic domain structure substantially equal to the first test element. The first test element is divided into the plurality of sections and the second test element is cut out from each section, and the magnetic domain structure of each second test element is examined, so that the magnetic domain structure of the portion corresponding to the sections of the plate-shaped body can be known. The cutting out direction (or angle) is determined such that a direction of main magnetic domains of the magnetic domain structure is perpendicular or substantially perpendicular to an in-plane direction with respect to a direction where vibration occurs. The magnetostrictive element 10 obtained by performing the cutting out in accordance with the cutting out direction determined in the above manner can have the characteristics exhibiting the sufficiently large magnetostriction amount in the longitudinal direction of the magnetostrictive element 10.

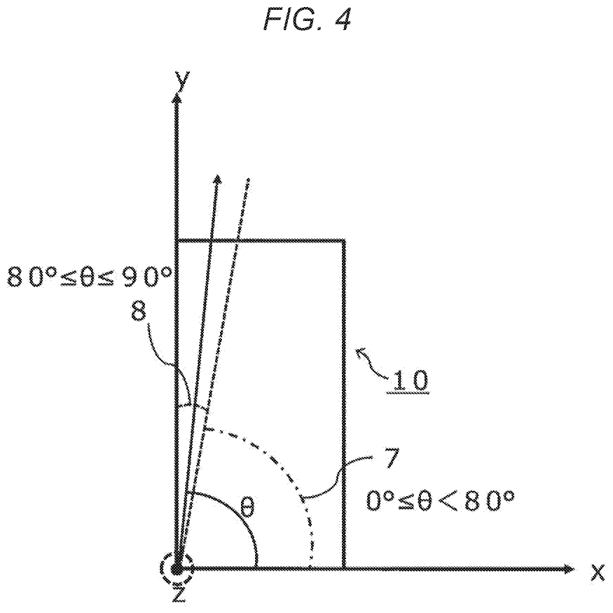

New characteristics of the magnetostrictive element 10 manufactured by the method described above will be described. FIG. 4 is a schematic view illustrating the characteristics of the magnetostrictive element 10 in the present embodiment. In FIG. 4, in order to facilitate understanding, an angle θ counterclockwise from the x-axis is measured with the x-axis as a reference (0°), but a value of the angle difference is understood as an absolute value of the angle θ.

For the magnetostrictive element 10 shown in FIGS. 1, 2, and 4, a case will be described where a magnetic field is applied parallel to an x-y plane formed by the x-axis and a y-axis and at the angle θ in a range of 0°≤θ≤90° with respect to the x-axis around an origin (x=y=0) of the x-y plane. For example, in FIG. 4, an example of the angle θ in a magnetic field application direction is indicated by an arrow. At this time, when the magnetostriction amount measured in the longitudinal direction (y-axis direction) is set as L, the magnetostrictive element 10 satisfies 150 ppm≤L≤1000 ppm. That is, the magnetostrictive element 10 exhibits the sufficiently large magnetostriction amount L in the longitudinal direction (y-axis direction).

At this time, the angle θ in the magnetic field application direction satisfies 80°≤θ≤90°. As shown in FIG. 4, when a region of the angle θ in the magnetic field application direction is divided into a region 7 satisfying 0°≤θ<80° and a region 8 satisfying 80°≤θ≤90° in a range of 0°≤θ≤90°. Since the magnetostrictive element 10 exhibits the larger magnetostriction amount particularly in the longitudinal direction (y-axis direction), the magnetostriction amount L is measured in the region 8 satisfying 80°≤θ≤90°.

In the present disclosure, the magnetostriction amount (ppm) refers to a rate of a dimensional change due to a magnetostrictive effect in the magnetostrictive material. In the present disclosure, the magnetostriction amount is measured in a room temperature environment (25° C.) by a commonly used strain gauge method. More specifically, in the present disclosure, the magnetostriction amount (ppm) of the magnetostrictive element 10 is set as a value when magnetostriction is saturated in a case where a gauge axis of a strain gauge is attached to be parallel to the longitudinal direction of the x-y plane of the magnetostrictive element 10, and a magnetic field is applied parallel to the x-y plane of the magnetostrictive element 10.

A vibration sample magnetometer (VSM) is used as a magnetic field generation device, and an intensity H of the magnetic field is measured as 0 Oe≤H≤10 kOe.

Accordingly, according to the method for manufacturing the magnetostrictive element 10 described above, when the magnetostrictive element is cut out from the single crystal alloy magnetostrictive material, a parallelism that is the angle difference between the lateral direction of the main plane and the direction of the main magnetic domains (magnetic domains that occupy 60% or more in the area rate) of the magnetic domain structure is 10° or less, that is, the direction of the main magnetic domains of the magnetic domain structure is perpendicular to the in-plane direction with respect to the direction where the vibration occurs, and thus a plurality of magnetostrictive elements 10 are obtained. Thereby, the magnetostrictive elements 10 can have equally suitable magnetostrictive characteristics. Specifically, a variation in the magnetostrictive characteristics in the longitudinal direction of each magnetostrictive element 10 can be reduced, the magnetostrictive elements 10 can have approximately suitable magnetostrictive characteristics, and can exhibit the sufficiently large magnetostriction amount in the longitudinal direction. As a result, when manufacturing the magnetostrictive element 10, it is not necessary to perform a sorting operation or the like, and the yield can be improved.

### EXAMPLES

Hereinafter, the disclosure will be described in more detail with reference to Examples and Comparative Examples, but the disclosure is not limited thereto.

In Examples, in order to evaluate an influence of the magnetic domain structure on a step of manufacturing the magnetostrictive element, a magnetostrictive element having the shape of the plate-shaped rectangular parallelepiped as shown in FIGS. 1 and 4 was produced from a Fe_{(100-α)}Ga_{α} single crystal alloy magnetostrictive material, and a magnetostriction amount was measured when a magnetic field was applied to the magnetostrictive element and saturation magnetization was performed thereon.

### <Production of Magnetostrictive Element>

The magnetostrictive element having the shape of the plate-shaped rectangular parallelepiped formed of the Fe_{(100-α)}Ga_{α} single crystal alloy magnetostrictive material was produced in Example 1 (Examples 1-1 to 1-3) and Comparative Example 1 (Comparative Examples 1-1 to 1-3).

First, Fe (purity 99.999%) and Ga (purity 99.999%) were weighed by separately making appropriate adjustment by using an electronic balance.

A single crystal alloy sample was grown using a high-frequency induction heating CZ furnace. A dense alumina crucible having an outer diameter of 45 mm was disposed inside a graphite crucible having an inner diameter of 50 mm, and for each weighed alloy sample, 400 g of raw materials of Fe and Ga were put into the crucible. The crucible into which the raw materials were put was put into a growth furnace, a vacuum was produced inside the furnace, and then an argon gas was introduced thereto. Thereafter, when inside of the furnace was under an atmospheric pressure, heating of the apparatus was started, and the heating was performed for 12 hours until the raw materials became a melt. A FeGa single crystal cut out in the <100> orientation was used as a seed crystal, and the seed crystal was lowered to near the melt. The seed crystal was gradually lowered while being rotated at 5 rpm, and a tip end of the seed crystal was brought into contact with the melt. The temperature was gradually lowered, and the seed crystal was lifted while rotating the seed crystal at a pulling speed of 1.0 mm/hr to cause crystal growth. As a result, a single crystal alloy was obtained, which had a diameter of 10 mm and a length of a straight body portion of 80 mm and was subjected to a heat treatment and produced into a columnar shape. The single crystal alloy had a <100> crystal orientation in a column height direction.

Thereafter, a plate-shaped body having a length (a first dimension along a first direction) in the column height direction (<100> crystal orientation) of 80 mm, which is the same as that of the straight body portion, a width (a second dimension along a second direction orthogonal to the first direction) of 10 mm, and a thickness (a dimension in a direction orthogonal to a plane having the first direction and the second direction) of 1 mm was cut out as a first test element from the straight body portion of the single crystal alloy obtained by the wire electric discharge machining.

Further, in order to check a magnetic domain structure, plate-shaped bodies each having a length (the dimension along the first direction) of 5 mm, a width (the dimension along the second direction) of 5 mm, and a thickness (the dimension in the direction orthogonal to the plane having the first direction and the second direction) of 1 mm were cut out as second test elements (referred to as α, β, and γ) one by one from sections corresponding to ⅓ lengths, an upper side, a middle side, and a lower side, of the first test element. At this time, the second test element a was cut out from a central portion of an upper edge of the section corresponding to the ⅓ length on the upper side of the first test element, the second test element β was cut out from a central portion of the section corresponding to the ⅓ length on the middle side of the first test element, and the second test element γ was cut out from a central portion of a lower edge of the section corresponding to the ⅓ length on the lower side of the first test element.

Thereafter, the second test elements α, β, and γ were used to observe magnetic domains in the sections corresponding to the second test elements by a method using a Kerr effect microscope. A cutting out direction of the magnetostrictive element was determined such that a total area rate of the magnetic domain was 60% to 100%. In the magnetic domain, an angle difference between a lateral direction of a main plane of the magnetostrictive element when the magnetostrictive element was produced and a direction of magnetic moments of the magnetic domain was 10° or less.

On a main plane of the second test element, a direction (the second direction) perpendicular to the column height direction (the first direction) was set as a reference (0°), an angle counterclockwise from the reference was measured, and an angle in a direction of the main magnetic domains was set as θ₁(°). In the present specification, the “main magnetic domains” means the magnetic domains that in total occupy 60% to 100% of an area of an observation region among the plurality of magnetic domains forming a magnetic domain structure of the observation region. The “direction of main magnetic domains” means a direction of magnetic moments of the main magnetic domains. The “area of main magnetic domains” means a total area of the main magnetic domains. θ₁ of the second test element α (cutting out position: upper side) was 0°, θ₁ of the second test element β (cutting out position: middle side) was 90°, and θ₁ of the second test element γ (cutting out position: lower side) was 90° (corresponding to θ₁ in Examples 1-1 to 1-3 and Comparative Examples 1-1 to 1-3 shown in Table 1) .

Angles θ₂ (°) in the cutting out direction in Examples 1-1 to 11-3 and Comparative Examples 1-1 to 1-3 were determined as shown in Table 1 by using the angles θ₁ obtained based on an observation result of the magnetic domains of the second test elements. The cutting out direction coincided with the longitudinal direction of the magnetostrictive element. The angle θ₂ in the cutting out direction was an angle measured counterclockwise from a reference) (0°) that was a direction (the second direction) perpendicular to the column height direction (the first direction) on the main plane of the magnetostrictive element. The cutting out directions θ₂ in Examples 1-1 to 1-3 were selected such that an angle difference between the direction of the main magnetic domains and the lateral direction of the finally acquired magnetostrictive element was 10° or less, and preferably 0°. The cutting out directions θ₂ in Comparative Examples 1-1 to 1-3 were all 90° such that the column height direction was the longitudinal direction regardless of the direction of the main magnetic domains.

Then, a plate-shaped body having substantially the same size as that of the first test element was cut out in parallel from a remaining portion of the straight body portion where the first test element of the single crystal alloy was cut out. From the plate-shaped body, each of the magnetostrictive elements in Examples 1-1 to 1-3 and Comparative Examples 1-1 to 1-3 was cut out in a plate-shaped rectangular parallelepiped shape having a thickness of 1 mm and including a main plane that has a length in the longitudinal direction of 10 mm and a width in the lateral direction of 5 mm such that the cutting out direction θ₂ coincided with the longitudinal direction of the magnetostrictive element.

Table 1 below shows conditions of the magnetostrictive elements in Examples 1-1 to 1-3 and Comparative Examples 1-1 to 1-3. Regarding the cutting out positions of the magnetostrictive elements, the upper side, the middle side, and the lower side indicate that the magnetostrictive elements were cut out from the sections same as those of the second test elements α, β, and γ, respectively. That is, the magnetostrictive elements in Example 1-1 and Comparative Example 1-1 were cut into the predetermined shape from portions of ⅓ lengths on upper sides (positions similar to positions where the second test elements a were cut out) that were portions of single crystal alloys grown in an early stage (portions pulled out from crucibles first). The magnetostrictive elements in Example 1-2 and Comparative example 1-2 were cut into the predetermined shape from portions of ⅓ lengths on middle sides, between upper portions and lower portions, of the single crystal alloys (positions similar to positions where the second test elements β were cut out). The magnetostrictive elements in Example 1-3 and Comparative Example 1-3 were cut into the predetermined shape from portions of ⅓ lengths on lower sides (positions similar to positions where the second test elements y were cut out) that were portions of the single crystal alloys grown in a late stage (portions pulled out from crucibles later) . In Table 1, the direction of the main magnetic domains and the area rate of the main magnetic domains show data obtained based on the observation result of the magnetic domains of the second test elements α, β, and γ. In Table 1, the area rate of the magnetic domains where the angle difference was 10° or less was calculated based on the direction of the main magnetic domains, the area rate of the main magnetic domains, and the cutting out direction. Further, the “angle difference was 10° or less” means that when the lateral direction of the main plane of the magnetostrictive element was set as a reference (0°), and an angle formed by turning the direction of the magnetic moments of the magnetic domain counterclockwise from the reference was measured, the measured angle was within ±10°. Further, Table 1 also shows measurement results of Ga concentrations and magnetostriction amounts L of the magnetostrictive elements.

TABLE 1

| | | | Direction | | | Area rate | |
|---|---|---|---|---|---|---|---|
| | | | of main | Area rate of | Cutting | of magnetic | Magneto- |
| | | Ga | magnetic | main | out | domain where angle | striction |
| | Cutting out | concentration | domains | magnetic | direction | difference is | amount L |
| | position | (at %) | θ₁ (° C.) | domains (%) | θ₂ (° C.) | 10° C. or less (%) | (Ppm) |
| Example 1-1 | Upper side | 15.8 | 0 | 60 | 90 | 60 | 206 |
| Example 1-2 | Middle side | 16.92 | 90 | 70 | 0 | 70 | 226 |
| Example 1-3 | Lower side | 16.84 | 90 | 95 | 0 | 95 | 364 |
| Comparative | Upper side | 15.32 | 0 | 65 | 90 | 65 | 201 |
| example 1-1 | | | | | | | |
| Comparative | Middle side | 16.79 | 90 | 75 | 90 | 25 | 84 |
| example 1-2 | | | | | | | |
| Comparative | | | | | | | |
| example 1-3 | Lower side | 17.03 | 90 | 100 | 90 | 0 | 3 |

Since the direction of the main magnetic domains of Example 1-1 is θ₁=0° and the cutting out orientation is θ₂=90°, the angle difference between the lateral direction of the magnetostrictive element and the direction of the main magnetic domains is within 10°. The magnetostriction amount L thereof satisfies 150 ppm≤L≤1000 ppm.

Since the direction of the main magnetic domains of Example 1-2 is θ₁=90° and the cutting out orientation is θ₂=0°, the angle difference between the lateral direction of the magnetostrictive element and the direction of the main magnetic domains is within 10°. The magnetostriction amount L thereof satisfies 150 ppm≤L≤1000 ppm.

Since the direction of the main magnetic domains of Example 1-3 is θ₁=90° and the cutting out orientation is θ₂=0°, the angle difference between the lateral direction of the magnetostrictive element and the direction of the main magnetic domains is within 10°. The magnetostriction amount L thereof is 300 ppm or more, which satisfies 150 ppm≤L≤1000 ppm.

Accordingly, the magnetic domains of the second test elements are observed, and the magnetostrictive element is cut out in accordance with the magnetic domain structure thereof such that the angle difference between the lateral direction and the orientation of the magnetic domain is within 10° . Thereby, it is understood that a variation in the magnetostrictive characteristics can be reduced and a yield can be increased.

In Comparative Examples 1-1 to 1-3, the cutting out directions were not determined in accordance with the magnetic domain structures, and the magnetostrictive elements were uniformly cut out at 90° in the height direction. As a result, it was confirmed that only in Comparative Example 1-1, the magnetostriction amount L exceeded 150 ppm, whereas the magnetostriction amounts L in the Comparative Examples 1-2 and 1-3 did not satisfy 150 ppm≤L≤1000 ppm, and the magnetostriction amount in Comparative Example 1-3 was 0.

Therefore, it is understood that in the related method in which the cutting out directions are unified, the variation in the magnetostriction amount is large, and the yield is further reduced.

Here, when the magnetostrictive element is cut out such that the direction of the main magnetic domains is within 10° with respect to the lateral direction, the magnetostriction amount is improved. This is because when a direction of an applied magnetic field is 90° with respect to the direction of the magnetic moments of the magnetic domain, it is considered that movement of a 90° magnetic domain wall is large, and a change in an in-plane magnetic flux density is large.

In the related method of performing cutting out along the crystal orientation, the variation is present in the magnetostriction amount, and a portion where the magnetostriction amount L does not satisfy 150 ppm≤L≤1000 ppm is also present. However, the variation in the magnetostrictive characteristics can be reduced and the large magnetostriction amount L (150 ppm≤L≤1000 ppm) can be acquired regardless of the position cut out from the single crystal alloy by cutting out the magnetostrictive element at the angle where the angle difference between the direction of the main magnetic domains and the lateral direction of the magnetostrictive element is within 10° . The magnetostriction amounts L satisfies 150 ppm≤L≤1000 ppm in all the magnetostrictive elements in Examples 1-1 to 1-3, whereas more than half of the magnetostriction amounts L do not satisfy 150 ppm≤L≤1000 ppm in Comparative Examples 1-1 to 1-3. Therefore, it is suggested that the usable region is increased to 50% or more, and thus the yield is improved by cutting out the magnetostrictive element such that the angle difference between the direction of the main magnetic domains and the lateral direction of the magnetostrictive element is 10° or less.

In the magnetostrictive element and the method for manufacturing the same of the disclosure, there are provided an FeGa-based magnetostrictive element having specific magnetostrictive characteristics in the longitudinal direction and exhibiting the sufficiently large magnetostriction amount in the longitudinal direction, and the method for manufacturing the FeGa-based magnetostrictive element. Therefore, according to the manufacturing method, the variation in the magnetostrictive characteristics of the magnetostrictive element cut out from the FeGa-based single crystal alloy can be reduced, and whereby the yield can be improved. Accordingly, the manufactured magnetostrictive element can be actively applied to a magnetostrictive vibration electric power generation device or the like for an autonomous electric power source for monitoring a social infrastructure or factory equipment.

What is claimed is:

1. A magnetostrictive element comprising a single crystal alloy magnetostrictive material, wherein
the magnetostrictive element has a shape of a plate-shaped rectangular parallelepiped,
a main plane of the plate-shaped rectangular parallelepiped includes a plurality of magnetic domains that are regions where atomic magnetic moments are arranged in the same direction and each have a width of 10 μm to 200 μm, and a total area rate of the magnetic domains where an angle difference between a lateral direction of the main plane and a direction of the magnetic moments of the magnetic domain is 10° or less to the main plane is 60% to 100%.

2. The magnetostrictive element according to claim 1, wherein
the magnetostrictive material is represented by the following formula (1)
Fe_{(100-α)}Ga_{α} (1)
(wherein α is a content (at %) of Ga and satisfies 14≤α≤19), or represented by the following formula (2)
Fe_{(100-α-β)}Ga_{α}X_{β} (2)
(wherein α is a content (at %) of Ga and β is a content (at %) of X; X is one or more elements selected from the group consisting of Ce, Sm, Eu, Gd, Tb, Dy, Cu, and C; and α and β satisfy 14≤α≤19 and 0.05≤β≤1).

3. A method for manufacturing a magnetostrictive element, comprising:
preparing a single crystal alloy magnetostrictive material subjected to a heat treatment and produced into a columnar shape,
cutting out, from the single crystal alloy magnetostrictive material, a first test element having a first dimension and a second dimension smaller than the first dimension respectively in a first direction parallel to a <100> crystal orientation of a single crystal alloy and in a second direction orthogonal to the first direction;
dividing the first test element into a plurality of sections along the first direction, and cutting out at least one second test element from each of the plurality of sections;
observing a magnetic domain that is a region where atomic magnetic moments are arranged in the same direction and each have a width of 10 μm to 200 μm for each of the second test elements; and
cutting out a magnetostrictive element, by using an observation result of the magnetic domains of the second test elements corresponding to the plurality of sections, from a remaining portion where the first test element of the single crystal alloy magnetostrictive material is cut out, wherein
the magnetostrictive element has a shape of a plate-shaped rectangular parallelepiped, a main plane of the plate-shaped rectangular parallelepiped includes a plurality of magnetic domains that are regions where atomic magnetic moments are arranged in the same direction and whose width is 10 μm to 200 μm, and a total area rate of a magnetic domain where an angle difference between a lateral direction of the main plane and a direction of the magnetic moments of the magnetic domain is 10° or less to the main plane is 60% to 100%.

4. The method for manufacturing a magnetostrictive element according to claim 3, wherein
the plurality of sections are portions obtained by dividing the first test element into three along the first direction.

5. The method for manufacturing a magnetostrictive element according to claim 4, wherein
the magnetostrictive material is represented by the following formula (1)
Fe_{(100-α)}Ga_{α} (1) (wherein α is a content (at %) of Ga and satisfies 14≤α≤19), or represented by the following formula (2)
Fe_{(100-α-β)}Ga_{α}X_{β} (2) (wherein a is a content (at %) of Ga and β is a content (at %) of X; X is one or more elements selected from the group consisting of Ce, Sm, Eu, Gd, Tb, Dy, Cu, and C; and α and β satisfy 14≤α≤19 and 0.05≤β≤1).

6. The method for manufacturing a magnetostrictive element according to claim 3, wherein
the magnetostrictive material is represented by the following formula (1)
Fe_{(100-α)}Ga_{α} (1) (wherein α is a content (at %) of Ga and satisfies 14≤α≤19), or represented by the following formula (2)
Fe_{(100-α-β)}Ga_{α}X_{β} (2) (wherein α a is a content (at %) of Ga and β is a content (at %) of X; X is one or more elements selected from the group consisting of Ce, Sm, Eu, Gd, Tb, Dy, Cu, and C; and α and β satisfy 14≤α≤19 and 0.05≤β≤1).
